(19) United States
(12) Patent Application Publication
(10) Pub. No.: US 2009/0263968 A1
(43) Pub. Date: Oct. 22, 2009

(54) METHOD OF FABRICATING SEMICONDUCTOR DEVICE

(75) Inventor: Kenji Komeda, Chuo-ku (JP)

Correspondence Address: SUGHRUE MION, PLLC, 2100 PENNSYLVANIA AVENUE, N.W., SUITE 800, WASHINGTON, DC, 20037, US

(73) Assignee: ELPIDA MEMORY, INC., Tokyo (JP)

(21) Appl. No.: 12/421,929

(22) Filed: Apr. 10, 2009

(30) Foreign Application Priority Data
Apr. 18, 2008 (JP) 2008-109039

(51) Int. Cl. H01L 21/44

(52) U.S. Cl. 438/669; 257/E21.158

(57) ABSTRACT

A method of fabricating a semiconductor device includes: forming a conductive film over a semiconductor wafer; forming a mask film over the conductive film; removing a portion of the mask film covering at least a peripheral portion of the semiconductor wafer such that a portion of the mask film covering a device forming region of the semiconductor wafer remains; and removing an exposed portion of the conductive film with use of the remaining portion of the mask film as a mask.

### BACKGROUND OF THE INVENTION

1. Field of the Invention

The present invention relates to a method of fabricating a semiconductor device and, more particularly, to a technique associated with a process including forming a conductive film and processing a peripheral portion of a semiconductor wafer.

2. Description of Related Art

In recent years, in the fabrication of semiconductor devices, generation of foreign particles from a wafer peripheral portion including a bevel portion has become a problem. This problem is particularly noticeable in a fabrication process carried out in a wet atmosphere, such as a damascene wiring forming process including a CMP (Chemical Mechanical Polish) step, a process for forming a crown-shaped capacitor in DRAM, and a photolithography step using a liquid immersion exposure apparatus.

Approaches to solve problems associated with the wafer peripheral portion are described in Japanese Patent Laid-Open No. 2005-311339, Japanese Patent Laid-Open No. 2007-059434, Japanese Patent Laid-Open No. 2005-19592, and Japanese Patent Laid-Open No. 10-125687, for example.

Japanese Patent Laid-Open No. 2005-311339 describes a method of removing a portion of a conductive film attached to the bevel portion at the same time with pattern formation, by conducting isotropic etching in a step of forming electrodes and wiring by processing the conductive film. However, because such isotropic etching is conducted under the condition that miniature patterns of electrodes and wiring are present in a chip region of the wafer, a problem exists that a deleterious effect on these miniature patterns cannot be avoided. If processing is performed so as to avoid the deleterious effect on the miniature patterns, a problem arises that the process margin is narrowed. Japanese Patent Laid-Open No. 2005-311339 also proposes a method including: forming a protective film covering a region on the wafer other than the bevel portion after formation of electrodes or wiring by anisotropic etching of a conductive film; and isotropically etching the entire surface of the wafer with use of the protective film (oxide film or silicon nitride film) as a mask to remove etching residues on the bevel portion. With this method, however, there is a problem that the fabrication process becomes complicated while increasing the fabrication cost since the steps of forming and removing the protective film are necessary.

Japanese Patent Laid-Open No. 2007-059434 describes a method employed in a Cu wiring forming step, including: forming an interlayer insulating film (film of an organic low-dielectric-constant material) and then forming a protective film (silicon oxide film) covering the observe surface and side surface of a substrate and reaching the reverse surface of the substrate, the protective film having a higher etching selectivity than the interlayer insulating film; and removing a portion of the protective film lying on a chip region in such a manner as to allow the rest of the protective film covering the bevel portion to remain. With the protective film remaining on a wafer edge portion, a groove for wiring is formed in the interlayer insulating film and then a metal film is formed in such a manner as to fill the groove. Thereafter, a portion of the metal film attached to the wafer edge portion is removed by wet etching and then the portion of the protective film covering the wafer edge portion is removed by spin etching using an etching solution. Subsequently, the metal film is subjected to a CMP process to form wiring in the groove. Japanese Patent Laid-Open No. 2007-059434 describes that this method can prevent the film from peeling off the wafer edge portion. However, there is a problem that the fabrication process becomes complicated while increasing the fabrication cost since the steps of forming and removing the protective film are necessary.

Japanese Patent Laid-Open No. 2005-19592 describes a method employed in fabrication of metal plugs, including: forming a metal film over an insulating film formed with a hole in such a manner that the metal film fills the hole; removing a portion of the metal film that lies on a wafer peripheral portion; and then removing a portion of the metal film that lies off the hole. Specifically, the metal film includes a first metal film extending to cover the wafer edge portion, and a second metal film formed on the first metal film so as not to lie on the wafer edge portion. By utilizing the difference in thickness between the portion of the metal film lying on the wafer edge portion and the portion of the metal film lying on the chip forming region, the portion of the first metal film lying on the wafer edge portion is removed by wet etching of the type using a nozzle or by etch back relying upon dry etching. However, the wet etching of the type using a nozzle probably cannot satisfactorily prevent the generation of foreign particles because the wet etching of this type has a difficulty in completely removing the portion of the metal film that is formed over minute unevenness present in the bevel portion. Also, since the metal film that is formed on the chip forming region is of a type similar to the metal film that is formed on the edge portion, there is a danger of undesirably etching the portion of the metal film lying on the chip forming region due to splashing of the wet etching liquid thereonto, thereby lowering the fabrication yield. What is more, in the case where the portion of the metal film lying on the wafer edge portion is removed by etch back, the portion of the metal film lying on the chip forming region needs to have a sufficient thickness and, for this reason, application of this method to a thin film forming process is difficult. When such a sufficient thickness cannot be ensured, a problem arises that removal of the portion of the metal film lying on the wafer edge portion becomes insufficient.

Japanese Patent Laid-Open No. 10-125687 describes a method of removing the portion of the metal film lying on the wafer edge portion with use of a silica film as a mask instead of a resist film. However, there is a problem that the fabrication process becomes complicated while increasing the fabrication cost since the steps of forming and removing the mask are necessary.

### SUMMARY

In one embodiment in accordance with a first aspect, there is provided a method of fabricating a semiconductor device, including:

forming a conductive film over a semiconductor wafer;

forming a mask film over the conductive film;

removing a portion of the mask film covering at least a peripheral portion of the semiconductor wafer such that a portion of the mask film covering a device forming region of the semiconductor wafer remains; and

removing an exposed portion of the conductive film with use of the remaining portion of the mask film as a mask.

In another embodiment, there is provided the method of fabricating a semiconductor device, further including changing a shape of a remaining portion of the conductive film with use of the remaining portion of the mask film.

In another embodiment, there is provided the method of fabricating a semiconductor device, further including:

patterning the remaining portion of the mask film to form a mask pattern; and

patterning a remaining portion of the conductive film with use of the mask pattern as a mask.

In another embodiment, there is provided the method of fabricating a semiconductor device, wherein the exposed portion of the conductive film is removed by isotropic etching with use of the remaining portion of the mask film as a mask.

In another embodiment, there is provided the method of fabricating a semiconductor device, wherein the portion of the mask film covering at least the peripheral portion of the semiconductor wafer is removed by spin etching including applying an etching solution to a reverse side of the semiconductor wafer opposite away from an obverse side thereof where a device is to be formed, while spinning the semiconductor wafer.

In one embodiment in accordance with a second aspect, there is provided a method of fabricating a semiconductor device, including:

forming an interlayer film over a semiconductor wafer;

forming a hole in the interlayer film;

forming a conductive film over the interlayer film such that the conductive film covers an internal surface of the hole;

forming a mask film over the conductive film such that the mask film fills the hole;

removing a portion of the mask film covering at least a peripheral portion of the semiconductor wafer such that a portion of the mask film covering a device forming region of the semiconductor wafer remains;

removing an exposed portion of the conductive film with use of the remaining portion of the mask film as a mask;

removing both a portion of the mask film and a portion of the conductive film which remain outside the hole;

removing the mask film filled in the hole.

In another embodiment, there is provided the method of fabricating a semiconductor device, wherein the step of removing both the portion of the mask film and the portion of the conductive film which remain outside the hole is performed by chemical mechanical polishing.

In another embodiment, there is provided the method of fabricating a semiconductor device, further including:

removing the interlayer film to expose an outer side portion of the conductive film which remains in the hole;

forming a dielectric film on a surface of the conductive film; and

forming another conductive film on the dielectric film.

In another embodiment, there is provided the method of fabricating a semiconductor device, wherein the removal of the mask film filled in the hole and the removal of the interlayer film are performed simultaneously.

In another embodiment, there is provided the method of fabricating a semiconductor device, wherein the exposed portion of the conductive film is removed by isotropic etching with use of the remaining portion of the mask film as a mask.

In another embodiment, there is provided the method of fabricating a semiconductor device, wherein the portion of the mask film covering at least the peripheral portion of the semiconductor wafer is removed by spin etching including applying an etching solution to a reverse side of the semiconductor wafer opposite away from an obverse side thereof where a device is to be formed, while spinning the semiconductor wafer.

In another embodiment, there is provided the method of fabricating a semiconductor device, wherein the mask film is formed of a photoresist film, and

the step of removing the portion of the mask film covering at least the peripheral portion of the semiconductor wafer is performed by exposing the photoresist film to light.

According to an exemplary embodiment, it is possible to provide a method of fabricating a semiconductor device, which is capable of suppressing the generation of foreign particles from a wafer peripheral portion.

### BRIEF DESCRIPTION OF THE DRAWINGS

The above features and advantages of the present invention will be more apparent from the following description of certain preferred embodiments taken in conjunction with the accompanying drawings, in which:

FIGS. 1A to 1D are illustrations of one exemplary DRAM capacitor fabrication process (including sectional views of a capacitor forming portion);

FIGS. 2E to 2G are illustrations of the exemplary DRAM capacitor fabrication process (including sectional views of the capacitor forming portion);

FIGS. 3A to 3D are illustrations of the exemplary DRAM capacitor fabrication process (including sectional views of a wafer edge portion corresponding to the sectional views of FIGS. 1A to 1D);

FIGS. 4E to 4G are illustrations of a related DRAM capacitor fabrication process (including sectional views of a wafer edge portion corresponding to the sectional views of FIGS. 2E to 2G);

FIGS. 5E, 5E1 and 5E2 are illustrations of a DRAM capacitor fabrication process according to one embodiment of the present invention (including sectional views of a wafer edge portion corresponding to the sectional views of FIGS. 2E to 2G);

FIGS. 6F and 6G are illustrations of the DRAM capacitor fabrication process according to the embodiment of the present invention (including sectional views of the wafer edge portion illustrating process steps following the process steps illustrated in FIGS. 5E, 5E1 and 5E2); and

FIGS. 7E to 7G are illustrations of a DRAM capacitor fabrication process according to another embodiment of the present invention (including sectional views of a wafer edge portion corresponding to the sectional views of FIGS. 2E to 2G).

### DETAILED DESCRIPTION OF THE PREFERRED EMBODIMENTS

Hereinafter, preferred embodiments of the present invention will be described by way of exemplary applications to a process for forming a crown-shaped capacitor in DRAM.

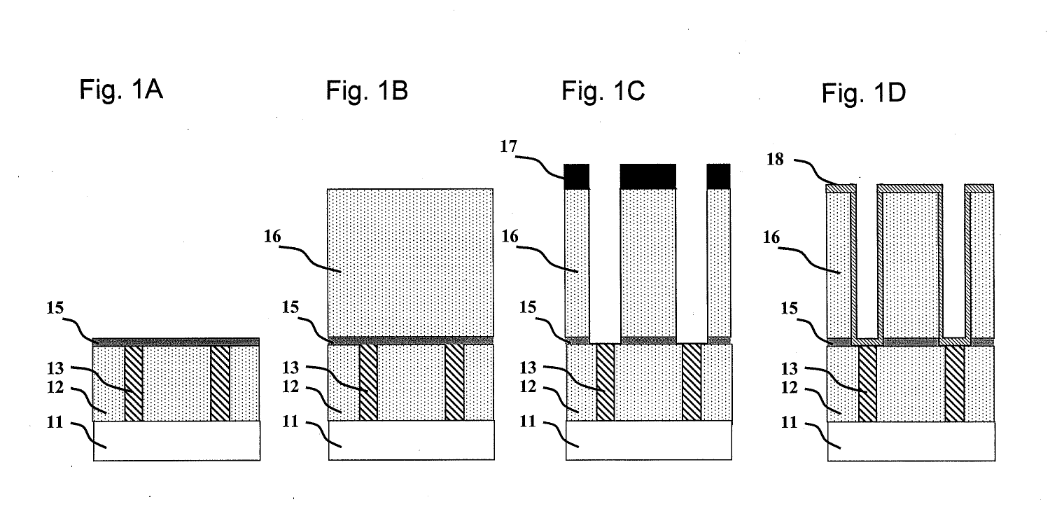

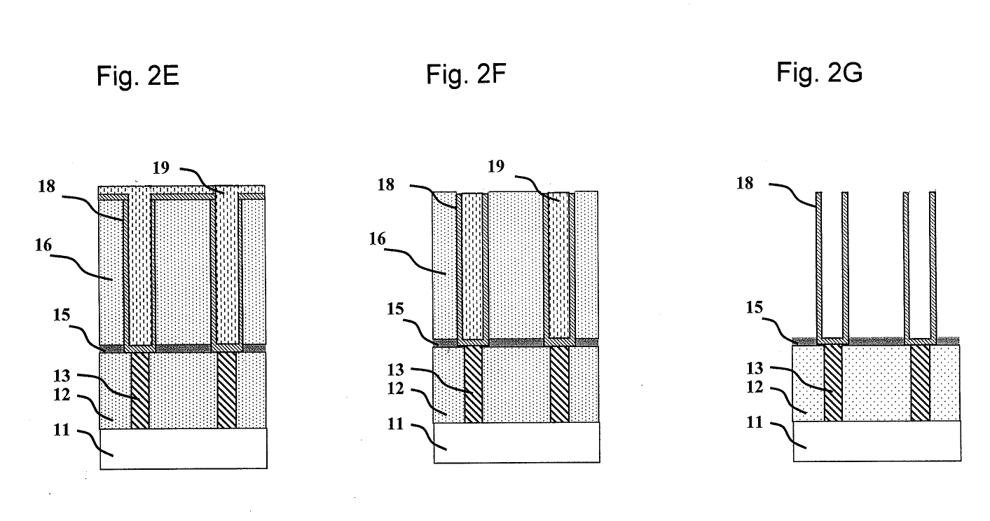

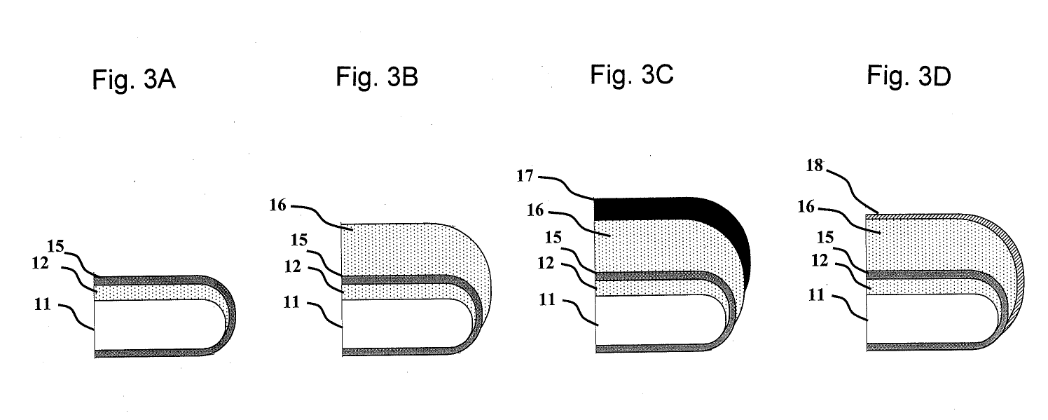

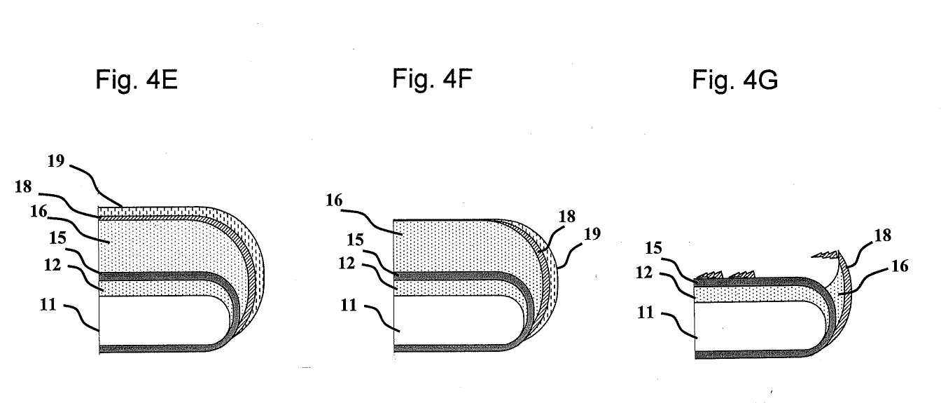

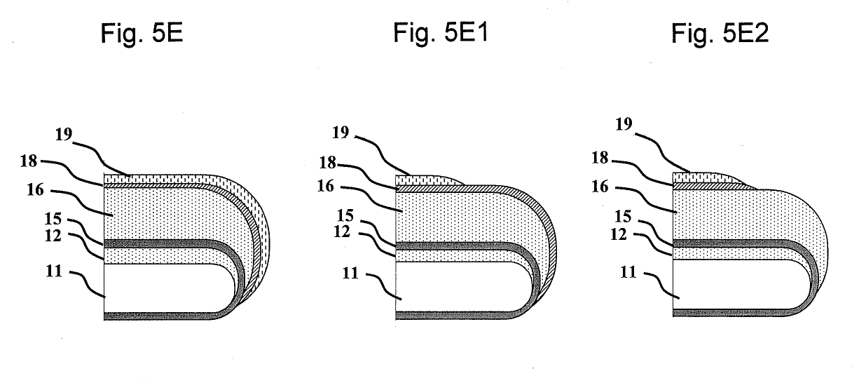

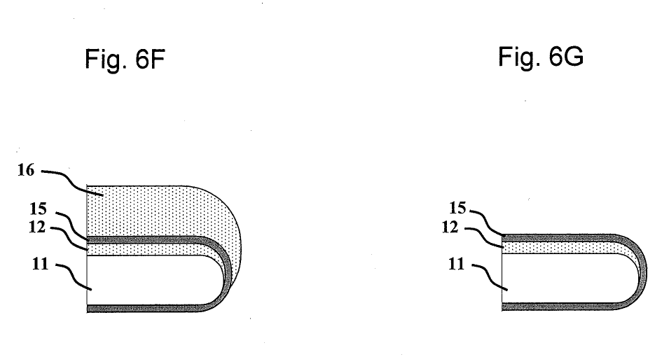

FIGS. 1A to 2G are sectional views illustrating process steps up to formation of a lower capacitor electrode. FIGS. 3A to 6G illustrate structures of a wafer peripheral portion (i.e., wafer edge portion) corresponding to the respective process steps illustrated in FIGS. 1A to 2G. Of these figures, FIGS. 4E to 4G illustrate structures of the wafer edge portion corresponding to respective process steps of a related method for comparison, while FIGS. 5A to 6G illustrate structures of the wafer edge portion corresponding to respective process steps of a method according to the present embodiment.

Initially, according to a common method, a silicon substrate (i.e., silicon wafer) 11 formed with a peripheral circuit and a memory cell control transistor is provided; an insulating film 12 is formed over the silicon substrate 11; contact plugs 13, each of which will connect a lower electrode of a capacitor to a conductive portion provided on the substrate side, are formed in the insulating film; and a stopper nitride film 15 is formed (see FIGS. 1A and 3A).

Subsequently, an interlayer film (hereinafter will be referred to as “cylinder interlayer film”) 16 for forming cylinder holes later is formed over the stopper nitride film 15 (see FIGS. 1B and 3B). The cylinder interlayer film 16 will be removed after formation of the lower capacitor electrode.

Subsequently, a photoresist pattern of 17 is formed over the cylinder interlayer film 16 by using a photolithographic technique; and the cylinder holes each reaching the associated contact plug 13 previously formed are formed by dry etching using the resist pattern as a mask (see FIGS. 1C and 3C).

Thereafter, a conductive film 18 (including a TiN film for example), which will form the lower electrode, is formed in such a manner as to cover an internal surface (including a sidewall surface and a bottom surface) of each cylinder hole (see FIGS. 1D and 3D).

Subsequently, a filling film 19 (including a silicon oxide film for example) is formed in such a manner as to fill each cylinder hole (see FIGS. 2E, 4E and 5E). The filling film 19 will protect a portion of the conductive film 18 lying in each cylinder hole during a CMP step to be performed later.

Subsequently, CMP is performed to remove a portion of the filling film 19 and a portion of the conductive film 18 that lie on an obverse surface of the wafer outside the cylinder holes (see FIGS. 2F and 4F). By so doing, the lower electrodes each of which is formed of the portion of the conductive film 18 lying in each cylinder hole are separated from each other. At that time, the portion of the conductive film 18 lying in each cylinder hole is protected by the filling film 19.

Subsequently, the filling film 19 and the cylinder interlayer film 16 are removed to expose the lower capacitor electrodes 18 (see FIG. 2G).

Subsequently, according to a common method not illustrated, a capacitive insulating film (including a hafnium oxide film for example) is formed in such a manner as to cover the lower capacitor electrodes 18 that is exposed, and then a conductive film (including a TiN film for example), which will form an upper electrode, is formed over the capacitive insulating film. Thereafter, this conductive film, along with the capacitive insulating film, is processed to have a desired shape by using a lithographic technique and a dry etching technique, thus giving a cylindrical capacitor.

Conventionally, the CMP step of the capacitor forming process described above is incapable of removing a portion of the filling film 19 and a portion of the conductive film 18 that are formed on the wafer peripheral portion (i.e., wafer edge portion) and a portion of the filling film 19 and a portion of the conductive film 18 that are formed on the reverse side of the wafer because a polishing pad used fails to contact these portions (see FIGS. 4E to 4F). The “wafer peripheral portion”, as used herein, is meant to include an obverse-side peripheral portion having a width of about 1 mm from the outermost periphery of the wafer and including an obverse-side rounded portion and a reverse-side peripheral portion extending from the outermost periphery of the wafer and including a reverse-side rounded portion. The obverse-side rounded portion and reverse side rounded portion of the wafer, which are called “bevel portions”, are included in the wafer peripheral portion (i.e., wafer edge portion).

The portion of the conductive film 18 which has not been able to be removed is peeled off the wafer edge portion in the step of removing the cylinder interlayer film 16 (see FIGS. 2F and 2G), to form foreign particles (see FIGS. 4F and 4G). Such a foreign particle has a size ranging from several micrometers to several millimeters and becomes a factor causing a serious defect when attached to a device forming region (i.e., chip forming region). Further, since about dozens to about several hundreds of such foreign particles are generated from the entire periphery of the wafer, the device yield rate lowers significantly.

In the present embodiment, after the formation of the filling film 19 (see FIGS. 2E and 5E), a portion of the filling film 19 that lies on the wafer edge portion (including the bevel portions), as well as a portion of the filling film 19 that lies on the reverse side of the wafer if present, is removed by a reverse-side etching technique, while a portion of the filling film 19 that lies on an obverse surface of the wafer exclusive of the wafer edge portion is allowed to remain (see FIG. 5E1).

Subsequently, using the remaining filling film 19 as a mask, a portion of the conductive film 18 that lies on the wafer edge portion (including the bevel portions), as well as a portion of the conductive film 18 that lies on the reverse side of the wafer if present, is removed by a wet etching process in which the entire wafer is immersed in an etching solution (see FIG. 5E2).

Subsequently, CMP is performed to remove the portion of the filling film 19 and the portion of the conductive film 18 that lie on the obverse surface of the wafer outside the cylinder holes in the same manner as described above, thereby separating the lower electrodes each formed of the portion of the conductive film 18 lying in each cylinder hole from each other (see FIGS. 2F and 6F).

Subsequently, the filling film 19 and the cylinder interlayer film 16 are removed to expose the lower capacitor electrodes 18 in the same manner as described above (see FIGS. 2G and 6G). At this process step, the portion of the conductive film 18 lying on the wafer edge portion (as well as the portion thereof lying on the reverse side of the wafer if present), which can be a generation source of foreign particles, has already been removed and, hence, any foreign particle is not generated (see FIG. 3G).

By performing succeeding process steps similar to those described above, a cylindrical capacitor can be obtained.

The capacitor forming process described above will be described more specifically.

The filling film 19 desirably is formed of a material which can be easily removed by CMP, more desirably a material which can be removed simultaneously with the removal of the cylinder interlayer film 16. Examples of such materials include: a CVD-type oxide film usually used for the cylinder interlayer film 16, such as a plasma SiO film or a BPSG film; a coating film which can be removed by a HF-type chemical liquid, such as SOD; an oxide film formed by an ALD (Atomic Layer Deposition) method; Al₂O₃ film; and HfO₂ film.

The filling film 19 may be formed of a material which cannot be removed simultaneously with the removal of the cylinder interlayer film 16. In this case, an additional step of removing the filling film 19 is needed which is separate from the step of removing the cylinder interlayer film 16. Such materials include polysilicon and SiN film.

The filling film 19 needs to have a thickness of not less than a half of the cylinder hole diameter (internal diameter). Taking the in-plane uniformity and the like of the filling film 19 in each cylinder hole into consideration, the thickness of the filling film 19 is preferably substantially equal to the cylinder hole diameter. When the cylinder hole diameter is 100 nm for example, the thickness of the filling film 19 needs to be at least about 50 nm, desirably not less than 100 nm.

In the present embodiment, between the step of forming the filling film 19 and the CMP step, the portion of the conductive film 18 lying on the wafer edge portion is removed by the aforementioned processing on the wafer edge portion, thereby preventing the generation of foreign particles in a later step.

The processing on the wafer edge portion conducted after the formation of the filling film 19 includes a first step of removing the portion of the filling film 19 lying on the wafer edge portion (including the bevel portions), as well as the portion of the filling film 19 lying on the reverse side of the wafer, by using the reverse-side etching technique in such a manner as to allow the portion of the filling film 19 lying on the obverse surface of the wafer to remain (see FIG. 5E1). By so doing, the portion of the conductive film 18 lying on the wafer edge portion (as well as the portion of the conductive film 18 lying on the reverse side of the wafer) is exposed.

The first step uses a chemical liquid exhibiting a sufficiently higher etching rate (i.e., sufficiently higher selective etching ratio) with respect to the filling film 19 than with respect to the conductive film 18. When the filling film 19 is an oxide film for example, it is possible to use the same HF-type chemical liquid as used in the step of removing the cylinder interlayer film 16.

The reverse-side etching can be achieved by a common spin etching method. For example, such a spin etching method includes applying an etching solution to a reverse side of a semiconductor wafer opposite away from an obverse side of the semiconductor wafer on which a device is to be formed while spinning the semiconductor wafer. Etching time is determined appropriately depending upon the type of the material used for the filling film 19, the thickness of the filling film 19 and the type of the chemical liquid used. The amount of the chemical liquid to flow around to the obverse side of the wafer after having been dropped onto the reverse side of the wafer can be adjusted by adjusting the number of revolutions of the wafer caused by reverse-side etching equipment. When the number of revolutions of the wafer is set to 1,200 rpm for example, the chemical liquid is allowed to flow around to the obverse side of the wafer by about 1 mm. Thus, the filling film 19 can be removed selectively (i.e., without removal of the conductive film 18) and partially (i.e., only the portions of the filling film 19 lying on the wafer edge portion and on the reverse side of the wafer are removed without removal of the portion of the filling film 19 lying on the obverse surface of the wafer).

The processing further includes a second step of removing the portion of the conductive film 18 lying on the wafer edge portion (including the bevel portions) which can be a generation source of foreign particles (as well as the portion of the conductive film 18 lying on the reverse side of the wafer) by immersing the entire wafer in a chemical liquid exhibiting a sufficiently higher etching rate (i.e., sufficiently higher selective etching ratio) with respect to the conductive film 18 than with respect to the filling film 19. At that time, the portion of the filling film 19 lying on the portion of the conductive film 18 in the device forming region functions as a mask to protect the device forming region on the obverse side of the wafer.

When the conductive film 18 is formed of a TiN film for example, the chemical liquid used in the second step may include ammonia-hydrogen peroxide water (mixture of NH₃ and hydrogen peroxide water, hereinafter will be referred to as “APM”), sulfuric acid-hydrogen peroxide water (mixture of sulfuric acid and hydrogen peroxide water), or a like chemical liquid which can easily etch the TiN film and can hardly etch an oxide film.

Etching time in the second step may be determined appropriately depending upon the type of the material used for the conductive film 18, the thickness of the conductive film 18 and the type of the chemical liquid used.

The lower capacitor electrode forming process according to the present embodiment and the conventional lower capacitor electrode forming process were carried out. The number of foreign particles generated after the step of removing the cylinder interlayer film 16 (see FIG. 1G) was measured. In the measurement of foreign particles, a bright-field defect inspection system manufactured by KLA-Tencor Corporation was used and foreign particles each having a size of not less than 5 μm were subject to the measurement. The results of the measurement are shown in Table 1. The numeric values in Table 1 each indicate the number of foreign particles per wafer (number/wf).

Each of the processes for forming the lower capacitor electrode 18 was carried out three times in the same manner and the number of foreign particles was measured for each run. In each process, a TiN film having a thickness of 15 nm and an oxide film grown to a thickness of 200 nm by the ALD method were formed as the conductive film 18 and the filling film 19, respectively. In the reverse-side etching process, hydrofluoric acid at 55° C. was used as a chemical liquid and the etching time was 10 seconds. In removing the TiN film, APM was used as a chemical liquid and the etching time (time period for which the wafer was immersed in APM) was set to 10 minutes to sufficiently remove the exposed portion of the TiN film.

As can be seen from Table 1, the conventional process as a comparative example allowed dozens to several hundreds of foreign particles per wafer to be generated, whereas the example process in accordance with the embodiment of the present invention allowed no foreign particle per wafer to be generated. Therefore, the fabrication method according to the present embodiment is capable of preventing the generation of foreign particles.

TABLE 1

| | No. 1 | No. 2 | No. 3 |
|---|---|---|---|
| Example | 0 | 0 | 0 |
| Comparative | 430 | 810 | 60 |
| Example | | | |

Instead of the above-described reverse-side etching process, use may be made of a technique which is capable of removing a film lying only on the wafer edge portion, such as a bevel etcher. In the step of removing the portion of the conductive film 18 lying on the wafer edge portion, an isotropic dry etching process may be used instead of the above-described wet etching process.

While one exemplary application of the present invention to the crown-shaped capacitor forming process has been described above, the present invention may be applied to processing on a conductive film with use of an oxide or nitride film, a polysilicon film or the like as a hard mask in a microfabrication process for gates or wiring for example. Examples of such processing include a process described below.

Initially, a conductive film is formed over an insulating film on a wafer and then a mask film is formed over the conductive film.

Subsequently, in the same manner as in the foregoing processing on the wafer edge portion, a portion of the mask film that covers the wafer edge portion is removed in such a manner that a portion of the mask film that covers the device forming region of the wafer is allowed to remain.

Subsequently, an exposed portion of the conductive film (i.e., the portion covering the wafer edge portion) is removed using the remaining portion of the mask film (i.e., the portion covering the device forming region) as a mask.

Subsequently, the remaining portion of the mask film is processed by a lithographic technique and a dry etching technique to form a mask pattern (hard mask).

Subsequently, dry etching is conducted to pattern the remaining portion of the conductive film with use of the mask pattern as a mask, thus forming wiring.

### Another Embodiment

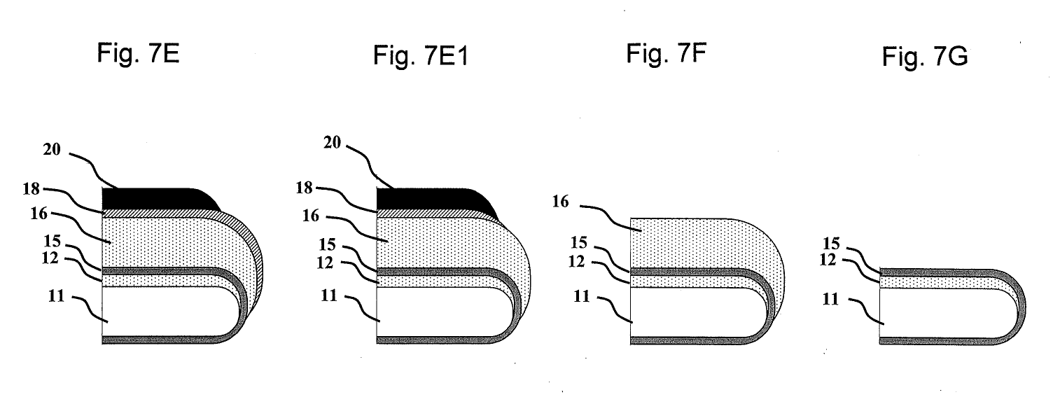

Another embodiment of the present invention will be described with reference to FIGS. 7E to 7G.

In a crown-shaped capacitor forming process according to the present embodiment, photoresist 20 is formed instead of the filling film 19. After the formation of the conductive film 18, a resist pattern is formed by a photolithographic technique so as to protect only the device forming region by the photoresist 20 (see FIG. 7E).

Thereafter, the portion of the conductive film 18 lying on the wafer edge portion is removed in the same manner as in the second step of the foregoing processing on the wafer edge portion (i.e., the wet etching step for removing the portion of the conductive film 18 lying on the wafer edge portion) (see FIG. 7E1).

Subsequently, the CMP step is performed in the same manner as in the foregoing embodiment with use of the photoresist 20 as a filling film, to remove the portion of the photoresist 20 and the portion of the conductive film 18 that lie on the obverse surface of the wafer outside the cylinder holes, thereby separating the lower electrodes 18 in the respective cylinder holes from each other (see FIG. 7F).

The present embodiment eliminates the first step of the aforementioned processing on the wafer edge portion (i.e., the step of removing the portion of the filling film 19 lying on the wafer edge portion) and hence has the advantage of a reduced number of process steps. The present embodiment has another advantage of being capable of defining a protected region of a wafer as desired by adjusting the exposure conditions. However, the removal of the portion of the photoresist 20 lying in each cylinder hole has to be conducted separately from the removal of the cylinder interlayer film 16. It is desirable that the removal of the portion of the photoresist 20 lying in each cylinder hole be conducted prior to the removal of the cylinder interlayer film 16 in order to prevent the lower electrode from collapsing.

Such a process is possible which includes: removing the photoresist 20 after the removal of the portion of the conductive film 18 lying on the wafer edge portion (as well as the portion of the conductive film 18 lying on the reverse side of the wafer); forming a new filling film such as the filling film 19; and performing the CMP step to remove the portion of the filling film and the portion of the conductive film 18 that lie on the obverse surface of the wafer outside the cylinder holes, thereby separating the lower electrodes 18 in the respective cylinder holes from each other.

As has been described above, the embodiments of the present invention make it possible to remove the portions of the conductive film lying on the wafer edge portion and on the reverse side of the wafer without the need to increase the number of necessary process steps significantly and without narrowing the process margin, thereby to suppress the generation of foreign particles originating from those portions of the conductive film. Since the generation of foreign particles can be reduced, the device yield rate can be improved. Further, since there is no need to provide an additional film forming process or to narrow the process margin, the process cost can be limited to a low level.

It is apparent that the present invention is not limited to the above embodiments, but may be modified and changed without departing from the scope and spirit of the invention.

What is claimed is:

1. A method of fabricating a semiconductor device, comprising:
forming a conductive film over a semiconductor wafer;
forming a mask film over the conductive film;
removing a portion of the mask film covering at least a peripheral portion of the semiconductor wafer such that a portion of the mask film covering a device forming region of the semiconductor wafer remains; and
removing an exposed portion of the conductive film with use of the remaining portion of the mask film as a mask.

2. The method of fabricating a semiconductor device according to claim 1, further comprising changing a shape of a remaining portion of the conductive film with use of the remaining portion of the mask film.

3. The method of fabricating a semiconductor device according to claim 2, wherein an electrode of a capacitor is formed by using the conductive film after the shape-changing step.

4. The method of fabricating a semiconductor device according to claim 1, further comprising:
patterning the remaining portion of the mask film to form a mask pattern; and
patterning a remaining portion of the conductive film with use of the mask pattern as a mask.

5. The method of fabricating a semiconductor device according to claim 4, wherein a wiring layer is formed by using the conductive film after the patterning step.

6. The method of fabricating a semiconductor device according to claim 1, wherein the exposed portion of the conductive film is removed by isotropic etching with use of the remaining portion of the mask film as a mask.

7. The method of fabricating a semiconductor device according to claim 1, wherein the portion of the mask film covering at least the peripheral portion of the semiconductor wafer is removed by spin etching including applying an etching solution to a reverse side of the semiconductor wafer opposite away from an obverse side thereof where a device is to be formed, while spinning the semiconductor wafer.

8. A method of fabricating a semiconductor device, comprising:
forming an interlayer film over a semiconductor wafer;
forming a hole in the interlayer film;
forming a conductive film over the interlayer film such that the conductive film covers an internal surface of the hole;
forming a mask film over the conductive film such that the mask film fills the hole;
removing a portion of the mask film covering at least a peripheral portion of the semiconductor wafer such that a portion of the mask film covering a device forming region of the semiconductor wafer remains;
removing an exposed portion of the conductive film with use of the remaining portion of the mask film as a mask;
removing both a portion of the mask film and a portion of the conductive film which remain outside the hole;
removing the mask film filled in the hole.

9. The method of fabricating a semiconductor device according to claim 8, wherein the step of removing both the portion of the mask film and the portion of the conductive film which remain outside the hole is performed by chemical mechanical polishing.

10. The method of fabricating a semiconductor device according to claim 8, further comprising:
removing the interlayer film to expose an outer side portion of the conductive film which remains in the hole;
forming a dielectric film on a surface of the conductive film; and
forming another conductive film on the dielectric film.

11. The method of fabricating a semiconductor device according to claim 10, wherein the removal of the mask film filled in the hole and the removal of the interlayer film are performed simultaneously.

12. The method of fabricating a semiconductor device according to claim 11, wherein a material of the mask film includes silicon oxide, and
the step of removing both the mask film filled in the hole and the interlayer film is performed by HF-type chemical liquid.

13. The method of fabricating a semiconductor device according to claim 8, wherein the exposed portion of the conductive film is removed by isotropic etching with use of the remaining portion of the mask film as a mask.

14. The method of fabricating a semiconductor device according to claim 8, wherein the portion of the mask film covering at least the peripheral portion of the semiconductor wafer is removed by spin etching including applying an etching solution to a reverse side of the semiconductor wafer opposite away from an obverse side thereof where a device is to be formed, while spinning the semiconductor wafer.

15. The method of fabricating a semiconductor device according to claim 8, wherein the mask film is formed of a photoresist film, and
the step of removing the portion of the mask film covering at least the peripheral portion of the semiconductor wafer is performed by exposing the photoresist film to light.

16. The method of fabricating a semiconductor device according to claim 8, wherein a material of the conductive film is TiN, and
the step of removing the exposed portion of the conductive film with use of the remaining portion of the mask film is performed by using a chemical liquid which includes any one of ammonia-hydrogen peroxide water and sulfuric acid-hydrogen peroxide water.
